(19) United States
(12) Patent Application Publication
(10) Pub. No.: US 2026/0352137 A1
(43) Pub. Date: Nov. 5, 2026

(54) DEVICE FOR THE RAPID TRANSFER OF THERMAL ENERGY, METHOD FOR THE REALIZATION OF THE SAID DEVICE AND SYSTEM FOR THE PRODUCTION OF ZERO-EMISSIONS ELECTRICITY FROM OTHER RENEWABLE SOURCES INTEGRATED WITH THE SAID DEVICE

(71) Applicants: Cosmo Turano, Vico Morcote (CH); Elis Mantovani, Breganzona (CH)

(72) Inventors: Cosmo TURANO, Vico Morcote (CH); Elis MANTOVANI, Breganzona (CH)

(21) Appl. No.: 19/114,803

(22) PCT Filed: Oct. 11, 2022
(86) PCT No.: PCT/IB2022/059719

§ 371 Date: Mar. 25, 2025

(51) Int. Cl. H02S 10/30

(52) U.S. Cl. CPC H02S 10/30

(57) ABSTRACT

The device (1) for rapidly transferring thermal energy from a thermal energy source (A) and capturing point or surface of said thermal energy to an arrival point (B) at a speed higher than the convective and conductive capacity of the adjacent means 2, allows the thermal energy to be converted into electrical energy with zero emissions harmful to the environment and to living beings, by means of thermoelectric conversion means 3 positioned at the arrival point B. The thermal energy is transferred by means of a coating 4 constituted by a plurality of nanometric layers with atoms which form ordered geometric structures (FIG. 1).

The invention also relates to a device for the transfer of thermal energy having a plurality of layers of carbonaceous material on a planar or non-planar (three-dimensional shape) opaque or transparent or translucent rigid or semi-rigid substrate of metallic or non-metallic or flexible material of fabric with natural or synthetic fibers or flexible but not opaque or transparent or translucent.

The present invention also comprises a method of producing a device for the rapid transfer of thermal energy (10 or 10a).

The said method comprising a deposition step of at least one layer (12,12a-12b-12c-12d, etc.) of carbonaceous material with an ordered geometric structure on a support substrate (11 or 11a) in an environment (110) of a machine of deposition (100), said environment being high vacuum and isolated from the external environment under controlled temperature and pressure conditions, said deposition taking place along an orthogonal or locally radial direction to a plane or shape substantially identified by said support substrate (11 or 11a).

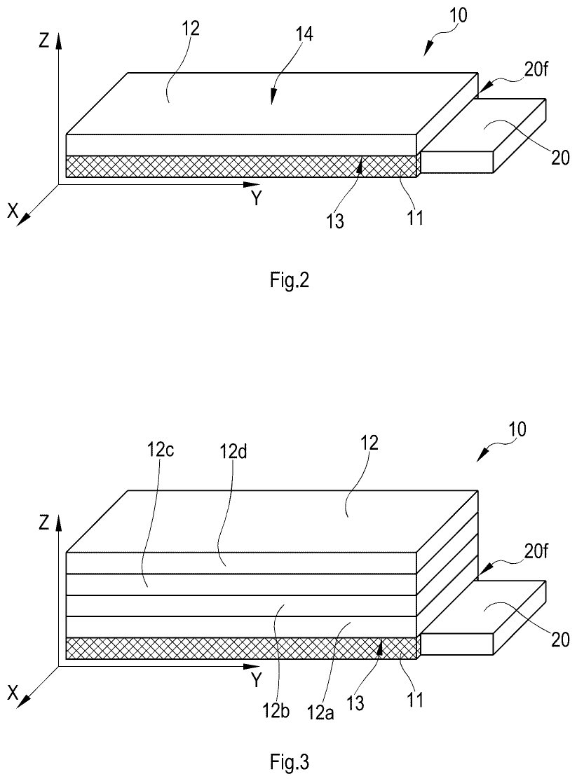

The invention also concerns an integrated system for the production of electrical energy using said device coupled to a thermoelectric generator and other possible generators from renewable sources of the type: photovoltaic and/or photovoltaic with thermoelectric and/or kinetic, all used jointly for the supply of electrical loads (FIGS. 2, 3, 4, 5, 6).

### FIELD OF TECHNIQUE

The present invention relates to the field of heat conducting devices.

In particular, the present invention relates to a device capable of capturing the thermal energy, hot or cold, which impacts on the surface of said device exposed to the thermal energy, present in the surrounding environment (air and/or solar radiation, therefore renewable source), or from other non-renewable sources, for the rapid transfer of said thermal energy captured from a point “A” to a point “B”.

In detail, the present invention relates to a device for the rapid transfer of thermal energy (hot or cold) at a speed higher than the convective capacity of the adjacent media.

Said device for the rapid transfer of thermal energy (hot or cold) according to the present invention is functional in the terrestrial environment (with atmosphere) and in space (without atmosphere).

In detail, the present invention relates to a device for the rapid transfer of thermal energy (hot or cold) at a speed higher than the convective capacity of the adjacent means and to a manufacturing method of the said device.

The present invention also relates to an integrated system for the production of electrical energy from renewable sources, in which a device is used for the rapid transfer of thermal energy according to the present invention coupled to a first generator of the thermoelectric type which feeds an electronic group integrating a possible second kinetic type generator and a possible third photovoltaic type generator assisted by a rapid transfer system of thermal energy coupled to a thermoelectric generator in order to cool the cells of the photovoltaic generator to improve its efficiency an to make up for the lack or insufficiency of radiation bright.

The problem of thermal energy transfer has been known for a long time: there are different types of thermal energy transfer systems which exploit convection or thermal conduction to extract heat or cold from a first body by directing it towards a second body.

For example, cooling systems for engines are known which use air or water or other fluids to transfer the heat to be subsequently dissipated via a radiating surface.

There are also refrigeration systems which also use gas heat pumps, similar to what happens in air conditioning systems.

There are also geothermal systems for using the heat present in the earth to heat or to produce electricity: these systems have important technical complications and considerably high costs.

These energy recovery systems, although now highly developed, have the drawback of a high thermal inertia, and are not capable of subtracting large quantities of thermal energy (heat or cold) from a body which undergoes, for example, sudden changes in temperature.

Furthermore, traditional heat pump systems are not suitable for energy recovery, as they require electricity, are too slow to respond, are too expensive to build and are bulky.

Many of the energy recovery devices, as well as materials that have good thermal conductivity, are in any case subject to a phenomenon of re-radiation of heat or cold towards the surrounding environment, and this limits their applications. In any case, these energy recovery devices are of reduced efficiency, and must be large in size even if only to supply small electrical loads.

For energy saving and for better comfort in internal environments there are systems and materials to avoid absorbing heat and vice versa to avoid dispersing heat; more and more “coat” coatings are applied to the external walls of buildings or for modern constructions of large buildings the external walls are glazed with special transparent “Flatt Glass” plates but equipped with good thermal insulation (good thermal insulation). All of these coatings are unable to transfer thermal energy and are unable to participate in or aid in any production of electricity or any other type of energy.

Also to vehicles, of any type (cars, trains, ships, etc.), more and more particular types of glass are applied which allow to reduce the passage of thermal energy towards the inside and vice versa towards the outside to improve comfort and to energy saving: even these types of glass are not able to participate in or to favor any production of electricity or other type of energy.

In order to produce electricity from the sun, there are photovoltaic panels that generate electricity by converting the energy brought by sunlight through photovoltaic cells: sunlight, however, also brings heat which overheats the photovoltaic cells which, when they exceed a certain threshold (normally after 25° C.) progressively reduce the production of electricity as the temperature increases, significantly lowering the % efficiency of the cells and therefore the production of electricity is greatly reduced.

The known coatings and the devices in which convective or conductive fluids are used are characterized by a high dissipation of thermal energy, and this gave birth to the inventor the idea of proposing an innovative device for the rapid transfer of said thermal energy to the purpose of producing electricity with zero emissions harmful to the environment and to all living beings.

Various systems and electronic units are also known for the supply of electrical energy with the characteristics of normal electrical distribution networks; to conform the electricity produced from renewable sources, for example through kinetic-type generators (for example mini or micro wind turbines) or through photovoltaic-type generators; these systems, very widespread and advanced, have an input threshold slightly lower than the nominal value of the operating voltage range, so that all the electrical energy produced with a voltage lower than said threshold, although of considerable power, is totally lost.

A first object of the present invention is to describe a device for the rapid transfer of thermal energy which is free from the drawbacks described above.

A second object of the present invention is also that of describing a production method of said device for the rapid transfer of thermal energy.

A third object of the present invention is also that of describing an integrated system of electric power supply from renewable sources which contributes to reducing the drawbacks described above and which is more energy efficient.

### CONCEPT OF THE INVENTION

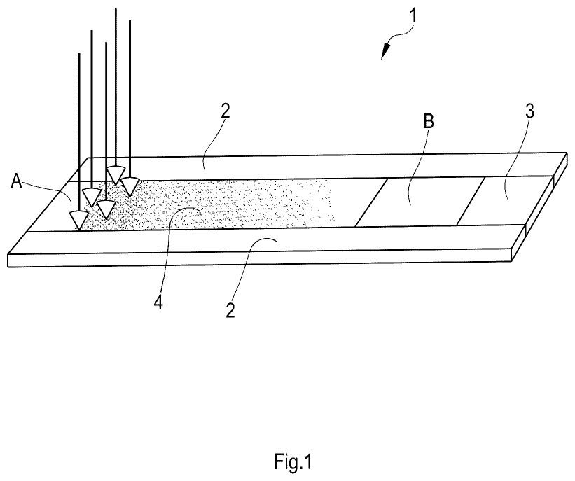

With reference to FIG. 1, a device 1 is made for rapidly transferring thermal energy from a source of thermal energy “A” and point or surface for capturing said thermal energy to an arrival point “B” at a speed exceeding the capacity convection and conduction of the adjacent means 2, allowing the thermal energy to be converted into electrical energy with zero emissions harmful to the environment and to living beings by means of a conversion device 3 positioned at the arrival point B. The thermal energy is transferred by means of a coating 4 consisting of a plurality of nanometric layers with atoms forming ordered geometric structures.

### SUMMARY OF THE INVENTION

According to the present invention, various energy recovery devices are provided characterized by high thermal conductivity (hot or cold) suitable for the rapid transfer of thermal energy, avoiding any type of dispersion in the fluids or other materials which may be in contact with said devices.

According to the present invention said devices are made in a nanotechnological environment by coating substrates (objects):
a) rigid, metal, glass or crystal (transparent or non-transparent plates), ceramic or porcelain, composed with vegetable or synthetic fibers;
b) semi-rigid, plastic, organic polymers or amorphous synthetic or semi-crystalline, composites with vegetable or synthetic fibers;
c) flexible, organic or synthetic fabrics.

Said device 1, according to the present invention is a structure of material a) or b) or c) acting as a support substrate comprising a first layer of thermally conductive carbonaceous material; said layer being superimposed on said surface of the structure acting as a support substrate and having an oriented geometrical molecular structure, and a thermoelectric converter in contact with said layer of heat conducting carbonaceous material.

The present invention also describes a production method of said devices for the rapid transfer of thermal energy; said method comprises at least one deposition step of at least one layer of carbonaceous material with an ordered geometric structure on a structure acting as a support substrate, made of transparent glass (without altering its transparency) or non-transparent glass or metal or other material a) or b) or c), in a Nano technological environment of a deposition machine.

Said nano-tech environment of a deposition machine being vacuum packed and isolated from the external environment under controlled temperature and pressure conditions; said deposition taking place along an orthogonal or locally radial direction to a plane or shape substantially identified by said support substrate.

Said deposition step advantageously comprises an acquisition step of at least one set of parameters with pressure and temperature values within said isolated environment, with voltage and frequency values of the substrate, for the correct management of the process.

Said deposition step comprises at least one magnetron for generating an electromagnetic field acting on at least a portion of said support substrate and an automatic control system of said intensity of said electromagnetic field by means of a data processing and emission of commands unit suitable for the dynamic parametric management of said deposition machine.

Said electromagnetic field intensity is adapted according to at least a part of said set of parameters for the dynamic parametric management of said deposition machine.

Said electromagnetic field is generated by a magnetron generator and wherein said deposition step comprises a relative continuous coordinated movement between said magnetron generator and said support substrate.

Advantageously, said method also comprises a previous pre-washing step and a washing step of said support substrate carried out before introducing said support substrate into the process chamber of the deposition machine.

According to the present invention there is described a device for transferring thermal energy, said device being characterized in that it comprises a support substrate and a plurality of layers of carbonaceous material with an ordered geometric structure acting as a thermal conducting means; said layers of carbonaceous material being superimposed on said support substrate; said device further comprising thermoelectric conversion means (inspired by well-known physical phenomena, ie the Peltier effect and the Seebeck effect), having at least a first surface and a second surface; said first surface being positioned in contact with the face of the stratification 12 opposite the face in contact with the support substrate 11 or 11a at a different distance from said first surface of said thermoelectric conversion means being subject in use to a thermal differential with respect to said first surface; said thermoelectric conversion means being capable of causing the production of electric energy as a function of said temperature differential. Advantageously, said thermoelectric conversion means comprise a first Peltier-like cell.

Advantageously, said thermoelectric conversion means further comprises a second Peltier-like cell, and wherein each of said first, second Peltier-like cells comprises said first and second surfaces; said second surface of said first Peltier-like cell being positioned in substantial proximity to said first surface of said second Peltier-like cell providing a means of recovering residual thermal energy generated by the operation of said first Peltier-like cell.

Advantageously, said rigid or semi-rigid or flexible support substrate is three-dimensional (non-flat).

Advantageously, each of said layers of carbonaceous material is heat conductive.

Advantageously, each of said layers of carbonaceous material has a predetermined percentage amount of sp² type bonds and a predominantly predetermined percentage amount of sp³ type bonds.

Advantageously, said thermoelectric conversion means comprise at least one similar Peltier cell or at least one similar thermocouple according to the Seebeck effect.

Finally, according to the present invention an integrated system for supplying electrical loads from renewable energy sources is provided, said system comprising at least one device for transferring thermal energy according to the present invention physically coupled to a first generator of the thermoelectric type which supplies power to an electronic unit integrating other generators from renewable sources such as a possible second kinetic type generator and a possible third photovoltaic type generator.

Advantageously, said electronic group having respective outputs electrically connected and feeding at least one stage of transformation of electric energy for feeding civil or industrial electric devices or loads.

Advantageously, there is a stage of electric energy batteries or accumulators, electrically connected to said electric energy transformation stage and configured to supply with an electric energy stored by them and coming from said thermoelectric converter and/or electric energy generators from renewable sources to said power supply of said energy transformation stage electricity in the event of a power failure from said thermoelectric converter and/or generators of electricity from renewable sources.

Advantageously, there is also a stage of electric energy batteries or accumulators electrically connected with said thermoelectric converter, with said generators of electric energy from renewable sources and with said electric energy transformation stage by means of a charge regulator stage capable of supplying said stage of electric energy batteries or accumulators at least when partially discharged; said charge regulator stage replacing the power supply of said electric energy transformation stage when an electric energy absorption required by said electric energy transformation stage is higher than the electric energy fed to it by said thermoelectric converter and/or by called generators of electricity from renewable sources.

Advantageously, said system also comprises at least a possible second kinetic generator of electric energy and a possible third photovoltaic generator of electric energy, capable of supplying together with said thermoelectric converter and/or said generators of electric energy from renewable sources, said transformation stage of electric energy.

Advantageously, this system further comprising a voltage converter of the Buck-Boost type, comprising inputs powered by said thermoelectric converter and/or said generators of electrical energy from renewable sources and an output supplying said electrical energy transformation stage and an input of called charge regulator stage. Advantageously, said generators of electric energy from renewable sources comprise at least one possible photovoltaic generator and at least one possible wind generator.

The invention will now be described with reference to the attached figures, which do not constitute any limitation to the generality of the invention itself, in which:

FIG. 1 illustrates the concept of the system: rapid transfer of thermal energy and conversion into electrical energy;

FIG. 2 illustrates a first embodiment of a device for the rapid transfer of thermal energy;

FIG. 3 illustrates a second embodiment of a device for the rapid transfer of thermal energy;

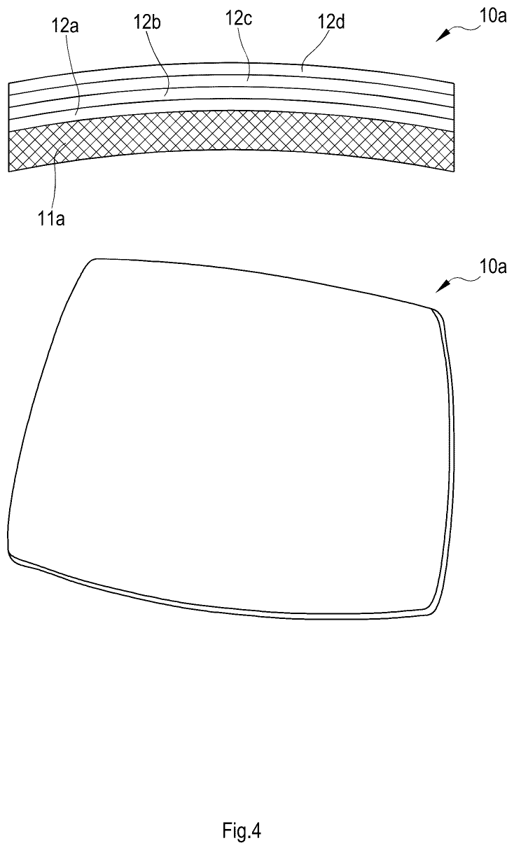

FIG. 4 illustrates a third three-dimensional embodiment of a device for the rapid transfer of thermal energy

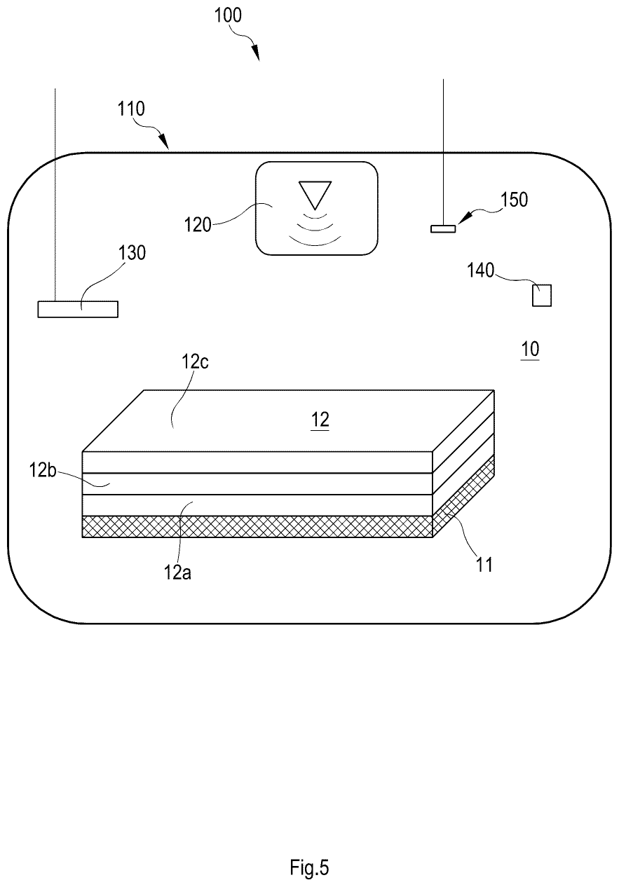

FIG. 5 shows a schematic representation of a machine for manufacturing the device of FIGS. 2 and 3;

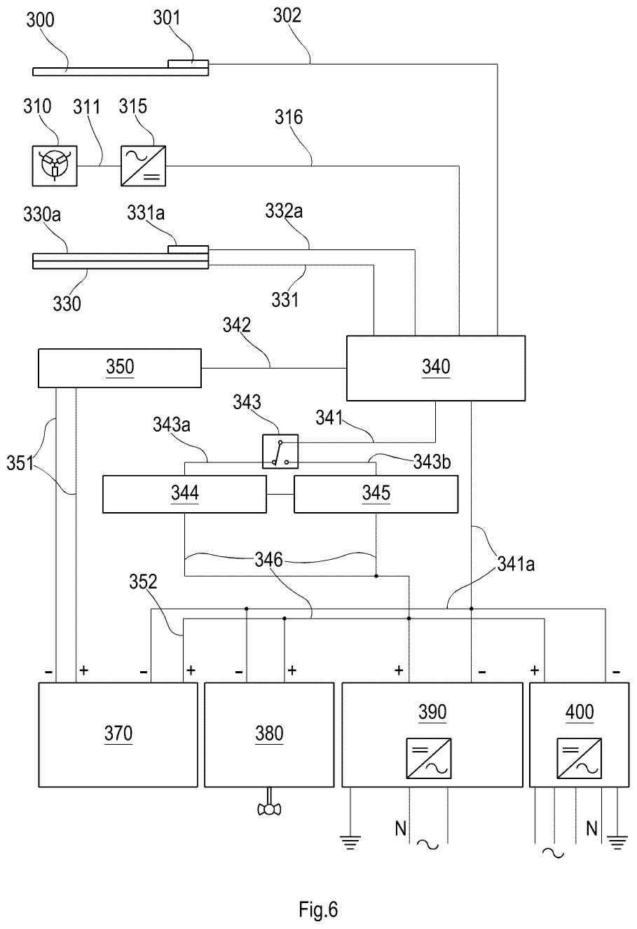

FIG. 6 illustrates a schematic representation of an integrated power supply system;

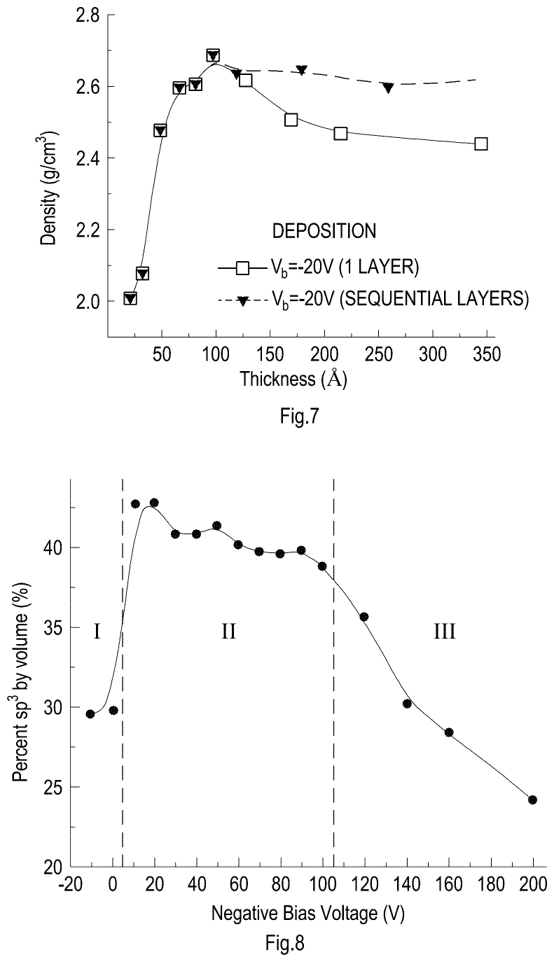

FIG. 7 and FIG. 8 each show a graph of a process detail of the processing for the purpose of obtaining the device according to the present invention, and in detail they concern a graph of density as a function of the thickness of a coating layer of carbonaceous material and a percentage of sp³-type bonds depending on the supply voltage of a substrate;

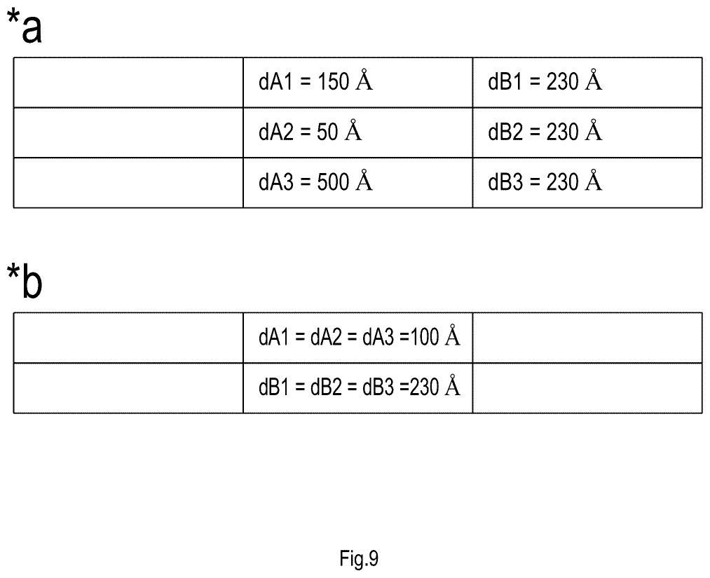

FIG. 9 illustrates a table of thickness values of layers of carbonaceous material.

### DETAILED DESCRIPTION OF THE INVENTION.

With reference to the annexed figures, the reference number 10 or 10a indicates as a whole a thermal energy transfer device, which is configured to convey the thermal energy in one or more substantially predetermined directions to allow its transformation into energy electric.

In detail, in a first embodiment, illustrated in FIG. 2, the device 10 comprises a support substrate 11 in rigid or semi-rigid or flexible material, substantially planar in shape and lying on a plane identified by a first pair of axes X, Y, on which at least one layer 12 of carbonaceous material is superimposed, which has an ideally uniform thickness over its entire surface, and which therefore identifies a first face 13 and a second face 14 opposite each other with respect to other and in detail respectively facing the substrate 11 and towards the outside.

The superimposition of the substrate 11 with the layer 12 of carbonaceous material takes place on an axis Z substantially orthogonal to the pair of axes X, Y, without this having to be interpreted in a limiting way, the various substrates include metals, glass or crystals (sheets transparent or non-transparent), ceramics or porcelain, compounds with vegetable or synthetic fibres.

The layer 12 makes it possible to provide a guide in at least one preferential direction of the thermal energy captured at the second face 14 of the layer 12 itself.

In a second embodiment, illustrated in FIG. 3, the device 10 according to the present invention is characterized by the presence of a plurality of carbonaceous layers 12a, 12b, 12c, 12d, etc. which are repeated with alternating sp³ carbon layers and sp²carbon layers until the expected total thickness is reached; all the sp³ layers, identical to each other, are thicker than the sp² layers.

In a third embodiment, FIG. 4 shows, in a non-limiting way, an example relating to a car windscreen; the device 10a according to the present invention comprises a support substrate 11a made of rigid or semi-rigid material (in the specific case it is laminated glass), with a three-dimensional shape on which is superimposed, along the Z axis or in the radial direction, a plurality of carbonaceous layers 12a, 12b, 12c, 12d, etc. which are repeated with alternating sp³ carbon layers and sp² carbon layers until the expected total thickness is reached; all the sp³ layers, identical to each other, are thicker than the sp² layers.

The device 10 or 10a according to the present invention is made by a process which comprises a first pre-washing phase and a washing phase, in which the substrate 11 or 11a is thoroughly cleaned so as to reduce the presence of impurities which could compromise the correct application of the first layer 12 of carbonaceous material. In detail, the first prewash phase is designed to proceed with the elimination of all impurities of the micrometric type and in the washing phase impurities of nanometric size are eliminated.

Since temperatures higher than 65° C. can be reached during the pre-washing step and the washing step, it is important that also the substrate 11 or 11a can be subjected to these temperatures without being damaged or altered.

Specifically, the pre-washing phase is performed in a first alternative solution using:
a preventive covering of the surface of the substrate with acetone;
a subsequent scrubbing step by means of a swab;
a subsequent rinsing step, preferably carried out with isopropyl alcohol (propan-2-ol: CH₃CH(OH)CH₃);
a subsequent drying phase of the substrate by blowing with nitrogen (N₂).
Alternatively, the cleaning phase may include, in addition to or in place of one or more of the previous phases:
an oxygen plasma etching phase, which removes the residual organic films;
a technical phase of RCA Clean, which removes metal, oxide and organic contaminants, and is performed in two phases: a first phase of organic cleaning, which advantageously removes insoluble organic contaminants with a 5:1:1 solution of H₂O:H₂O₂:NH₄OH; and a second phase called “Oxide Strip”, in which a thin layer of SiO₂ is removed in which metal contaminants may have accumulated.
a phase called “piranha clean” or “piranha etch”, which removes organic materials (photoresist, oils, etc.) which is obtained with 98% of H₂SO₄ and 30% of H₂O₄ in volumes 2-4:1, followed by heating the substrate thus cleaned to 100° C.;
an ultrasonic cleaning step, in which the substrate is placed in an ultrasonic cleaning device to remove contaminants.

An alternative substrate 11 or 11a cleaning solution has been observed in trials to include immersion in Piranha solution (H₂SO₂:H₂O₂ 7:3 for 10′), followed by ultrasonic cleaning.

If the substrate 11 or 11a is made of ferrous material, and particularly of steel, it is possible to opt for cleaning with NaOH, followed by ultrasonic cleaning.

Finally, regardless of the type of substrate, the cleaning step always ends with a deposition of the substrate 11 or 11a in an HV chamber, in which it is cleaned with low energy etching to avoid amorphization. At this point the substrate is ready to be processed.

The process continues in the vacuum chamber 110 of a deposition machine 100; within the vacuum chamber 110, through suitable vacuum pumps of the “Root” type and for ultra vacuum of the “turbomolecular” type capable of sucking the air from inside, a threshold pressure is reached (preferably less than 10⁻¹ Pa) following which a deposition step of one or a plurality of layers 12 of carbonaceous material takes place.

In detail, the deposition machine 100 comprises at least one magnetron unit 120 composed of one or a plurality of magnetron devices, movable or fixed when the substrate is being moved, positioned inside the vacuum chamber 110 and an inlet for gas 150 also with the end positioned in said vacuum chamber 110. The vacuum chamber 110 creates a clean environment, isolated from the outside, in which the following deposition phase takes place under controlled temperature and pressure conditions and suitably suitable for the type of support substrate 11 or 11a.

During the deposition phase, the magnetron unit 120 is activated and produces an electromagnetic field which strikes the substrate 11 or 11a in a precise manner during its movement substantially parallel to the profile identified by the substrate 11 or 11a. Substantially therefore, between the magnetron group 120 and the substrate 11 or 11a there occurs a movement relative to the profile, planar on the X-Y axes or three-dimensional on the X-Y-Z and/or radial axes, which allows a deposition of the layer or of the plurality of nanometric layers of carbonaceous material in a very precise way, compared to a traditional sputtering technique, guaranteeing homogeneous stratifications with a high degree of regularity for both types of layers with sp³ bonds and with sp² bonds.

Also inside the vacuum chamber 110 there is an electron gun 130 (integrated in the magnetron unit) which transmits an electron beam against a target 140 (always integrated in the magnetron unit) made of carbon or pure graphite at 99.99% of the preferably but not limitedly planar type positioned in contact with a suitable electrode. Carbon atoms directed towards the substrate 11 or 11a are released from the carbon target 140.

In detail, the target 140 was selected as at least 99.99% pure graphite, so as to be able to obtain a coating with an sp³ tetrahedral crystalline structure which has characteristics similar to diamonds.

However, other possible targets, taken into consideration for eventual and specific applications, are:
Ni (nickel) doped graphite, necessary to allow the growth of the nanotubes on the support substrate;
or pure Ni, as a catalyst for the growth process.

The purity of the graphite with a value of at least 99.99% is necessary to obtain the deposition of the plurality of layers 12 of highly efficient carbonaceous material, and to avoid spreading inside the vacuum chamber 110 impurities susceptible to create complications during the process and such as to increase, even significantly, the operating times due to the intervention of the quality control systems with which the deposition machine 100 is equipped.

The magnetron 120 is activated with physical parameters and with times depending on the methods and times relating to the introduction, within the chamber 110, of auxiliary technical gases, indispensable for the deposition process.

The deposition step can comprise one or more deposition steps of a layer 12 of carbonaceous material, with specific modalities for layers with sp³ bonds or for layers with sp² bonds, and according to the overall thickness to which the set of layers 12 is to be brought.

In detail, in fact, with a single deposition step, the deposition machine 100 allows the deposition of a layer 12 of sp³ or sp² carbonaceous material having a thickness measured along the Z axis-equal to a few nanometers and, in any case, to depending on whether it is sp³ (thickness greater than sp²) or if it is sp².

However, through multiple deposition steps, each layer 12 of carbonaceous material is superimposed on further homogeneous layers of sp³ alternating with homogeneous layers of sp² (sp² with a thickness lower than those of sp³) until a predetermined total thickness is reached according to the actual application considering that the maximum thickness is equal to 6 μm.

It should be noted that if the substrate does not have a planar shape but for example a cylindrical shape, the deposition of the various layers on the substrate 11a is substantially radial.

The number of layers 12 of carbonaceous material allows the amount of thermal energy to be determined a priori, as a function of the temperature differential, which the device 10 according to the present invention is capable of transferring.

In some cases, depending on the type of support substrate to be coated, a time interval is left between one deposition step and the next in order to keep the temperature below values likely to cause a reduction in the performance of the device 10.

During the deposition step, the substrate 11 or 11a can optionally be subjected to an electric voltage other than zero, which, as described below, can in some cases even reach a few hundreds of Volts. This voltage is known in technical jargon as the “bias voltage”.

In detail, called “bias voltage”, it favors the deposition process of the carbonaceous material on the substrate 11 or 11a.

By varying the electrical voltage to which the substrate is subjected, the percentage of sp² bonds, typical of graphite, varies in relation to the percentage of sp³ bonds, typical of diamond, which will be obtained in the overall layer of deposited carbonaceous material.

According to the present invention by sp² or sp³ bonds are meant those bonds generated by the hybridization process, which occurs on a predetermined number of orbitals (s, p, d orbitals) with content eslightly different energy; this bond allows to obtain new equivalent (isoenergetic) hybrid orbitals with lobes oriented along the directions of the possible bonds that the central atom of one or more molecules can form with other atoms.

In detail, three orbitals are involved in the sp² type orbital, one of which is of the “s” type and two of the “p” type; while, in the case of the sp³ bond, there is the hybridization of four orbitals, one of which is of the “s” type and three of the “p” type.

In particular, in fact, during the deposition phase, the carbonaceous material assumes a substantially crystalline form with an ordered geometric structure, similar to that of diamond; in particular, through the use of the magnetron/s 120 a geometric structure is recreated formed by a plurality of nanotubes which in a first and simpler embodiment of the deposition process are oriented in the same direction.

This means that during the various deposition steps of carbonaceous material, the bias voltages on the substrate 11 or 11a can vary, consequently varying the crystalline form of the carbonaceous material from layer to layer and consequently the characteristics of resistance, density and heat transfer capacity for each layer.

In detail, in the crystalline form desired for application on the device of the present invention, carbon has a prevalence of sp³-type bonds, typical of diamond, rather than sp²-type bonds, typical of graphite.

In particular, the crystalline structure is of the tetrahedral type.

It is preferable to have a deposition, along the Z or radial axis, of several layers of carbonaceous material with a thin height rather than having a single layer of carbonaceous material with a high height; in fact it has been discovered that by reducing the height of each layer of carbonaceous material deposited on the substrate 11 or 11a, and in particular lower than 100 nm per layer, it is possible to reduce the mechanical stress and the temperature of the layer itself during deposition, having advantageously a reduction in the percentage of sp²-type bonds typical of graphite, to the full advantage of the mechanical resistance and thermal conduction characteristic.

It has also been found that the reduction of mechanical stress avoids any fractures of the layer ensuring optimal conditions of thermal conductivity and conferring the necessary mechanical flexibility, an essential feature when the support substrate 11 or 11a is semi-rigid or when it is a fabric or other material without solid form.

Finally, further experiments have shown that the absolute greatest heat transfer efficiency is found when successive superimpositions of at least two and preferably more layers 12 of carbonaceous material are performed with a prevalence of bonds of the sp³ type separated by at least one layer 12 of carbonaceous material with a prevalence of sp²-type bonds.

As illustrated in FIG. 7, in fact, depending on whether a single layer of carbonaceous material is used or several layers superimposed on the substrate 11 or 11a in separate deposition steps, the density characteristics of the material change.

The diagram of FIG. 7 illustrates in detail a structure in which the substrate 11 or 11a was subjected to a bias voltage of −20V, both with a single deposition phase (continuous line), and with multiple deposition phases (solid line dotted). Now, it can be observed from this graph how the rapid growth of density for the lower thicknesses, along the Z or radial axis, indicates the presence of few micro voids: index of the generation of sp³-type bonds.

Arrived at about 70 Angstrom, FIG. 7, depending on whether there is a single layer or more layers of carbonaceous material, the density changes as the thickness increases, reducing in the case of a single layer to a value tending to about 2.44 g/cm³, while in the case of a plurality of layers it remains in the order of over 2.6 g/cm³ . This occurs because the continuous exposure to the ion bombardment of the support substrate assembly 11 or 11a and layer 12 of carbonaceous material causes an increase in temperature inside the layer 12, and therefore increases, consequently, the percentage of bonds of type sp².

FIG. 8 shows in detail how the variation of the bias voltage on the substrate 12 favours the formation of bonds of the sp² or sp³ type. The graph in question shows that between −20V and 0V the percentage of sp³ type bonds remains close to 30% and then suddenly increases in the range between 0 and 20V, stabilizing around 45% and then decaying between about 40% and 38% in the range substantially between 30V and 100V. Beyond this bias voltage value, a more rapid decay of the percentage of sp³ bonds is observed, which, except for a brief decline decreases linearly to just under 20% at a bias voltage of 200V.

The graph of FIG. 8 can therefore be divided into three sub-areas, a first (I) in which with bias voltages between −20V and 0V there is no ion bombardment by the carbon, which settles gently on the substrate 11 or 11a, the which is subjected only to the action of the technical gas introduced into the vacuum chamber 110; the carbon deposition therefore takes place in a condition of almost equilibrium.

Subsequently there is a second sub-area (II) [0-100]V, in which an ion sub-implantation mechanism is activated in the substrate, and a third sub-area (III) (100-200)V in which a thermalization process is activated. It should be noted that the voltages indicated in the graph are actually negative, i.e. the first sub-area actually corresponds to a positive substrate voltage.

An experiment was carried out in which layers of material with sp² bonds or with sp³ bonds are superimposed; a first layer 12 (called layer A) is deposited on the substrate 11 supplied with a bias voltage equal to 10V (V_{b}=−10V); a second layer 12 (called layer B) is deposited by feeding the substrate 11 with a bias voltage equal to −20V, and each layer is deposited in one or two or three sub-layers with a total thickness between dₐ and d_{b}. The total product thickness is equal to 900-1000-2600 Angstrom. The first deposition consists of a bilayer with dA1~150 Å, dB1~230 Å. From the second to the ninth deposition dA~50 Å. The total thickness is equal to 2620 Å. The content of sp³ depends on V_{b}. The first layer deposited A1 shows a low stress (1.35 GPa) and ensures good adhesion to the substrate 11. The first layer B1, deposited on A1, shows an increase in stress up to 4.5 GPa. The successive depositions of layers 12, both A and B have little effect. Above 1800 Å thickness the stress saturates at 5.2 GPa.

In order to evaluate the effect of the A layers in relation to the mean stress of the coating, the following group of layers 12 of carbonaceous materials was deposited: *a(~900 Å) and *b (~1000 Å). The thickness data are shown in the table in FIG. 9.

Some deposition “recipes” are given below which, in the course of the experiments carried out, have shown to allow the realization of particularly effective devices according to the present invention.

A first recipe, performed by sputtering with Magnetron on the previously described machine, includes:
target 140: 99.9999% pure graphite with a thickness of 10 mm (indicative) and a diameter of 75÷90 mm (indicative).
gases introduced into the vacuum chamber 110: CH₄;
pressure inside the vacuum chamber 110: 5*10⁻³ Torr;
total flow of gas inside the vacuum chamber 110:=70 Sccm (standard cubic centimeter per minute).
Magnetron parameters set: frequency f=13.56 MHz; Power=150 W.

The first recipe identified above has made it possible to create devices whose overall layer is, for example, equal to:
300 nm; 600 nm; 1 μm; 3 μm; 6 μm; 10 μm; 20 μm.

A second recipe performed with pulsed bipolar asymmetric sputtering includes:
target 140: 99.9999% pure graphite with a thickness of 10 mm (indicative) and a diameter of 75÷90 mm (indicative).
gases introduced into the vacuum chamber 110: Ar+7.5% CH₄;
pressure inside the vacuum chamber 110: 9.75*10⁻³ Torr;
Magnetron parameters set: Power density=4.4 W/cm² ;
Characteristics of the Pulsed DC signal on the Magnetron 120: Pulse=+37.5 V; Negative pulse=−(600÷700) V; Source used (indicative)=ENI RPG-50; Duty cycle=70%, obtained from a frequency equal to 150 kHz, with a positive impulse of 2016 ns; substrate bias power supply (−300÷0) V.

The second recipe identified above has also made it possible to create devices whose overall layer is, for example, equal to:
300 nm; 600 nm; 1 μm; 3 μm; 6 μm; 10 μm; 20 μm.

A third recipe performed with a sputtering with Magnetron is instead characterized by having the following parameters:
target 140: 99.9999% pure graphite with a thickness of 10 mm (indicative) and a diameter of 75÷90 mm (indicative).
gases introduced into the vacuum chamber 110: Ar+H₂ (0.7%);
pressure inside the vacuum chamber 110: 30*10⁻³ Torr;
total flow of gas inside the vacuum chamber 110: 40 Sccm (standard cubic centimeter per minute).
power set on the magnetron: 200 W

The third recipe was also tested with thicknesses of the carbonaceous material layer(s) of 300 nm; 600 nm; 1 μm; 3 μm; 6 μm; 10 μm; 20 μm.
catalyst agent: coating layer of 10 nm of Ni
   previously deposited on the substrate.
gases introduced into the vacuum chamber 110: 99.999% pure N₂;
pressure inside the vacuum chamber 110: 0.020 Torr;
total flow of gas inside the vacuum chamber 110: 30 Sccm (standard cubic centimeter for minutes).
set magnetron parameters: power 100 W;
bias voltage on the substrate: −20V.

The deposition process is advantageously capable of leaving the characteristics of the support substrate unaltered. This is particularly important if the support substrate must be an already known material or element, whose dimensional and mechanical strength characteristics must remain unchanged to allow the previously imposed task to be carried out and to maintain the compatibility of the installation on electromechanical or mechanical systems even of a complex type.

The process described also increases the resistance to chemical agents and to the action of eroding agents such as sand found in desert areas but also in coastal areas and which could cause even significant abrasion of the surface of the support substrate and layers of coating in carbonaceous material assembly.

Advantageously, therefore, the transport of thermal energy offered by the device 10 or 10a according to the present invention is of the anisotropic type and therefore has a preferential direction. However, this must not be understood in a limiting way, since it is possible to obtain different preferential directions for each layer 12 of carbonaceous material which is deposited on the previous one.

The machine 100 is equipped with a data processing unit, with specific software for managing the deposition process and with a plurality of sensors positioned inside the vacuum chamber 110, electrically connected with said data processing unit, which pilots—directly or through servo systems at least: the amount of energy and the frequency emitted by the magnetron/s, the operating pressure and the gas flow introduced inside the vacuum chamber 110 itself.

In detail, the quantity E of energy, the frequency emitted by the magnetron(s) and the flow F of gas are varied as a function of at least two parameters: the temperature of the substrate T_{sub} and the residual pressure inside the vacuum chamber P_{c}. Therefore, the data processing unit, by means of specific software, implements a feedback control in which at each instant of time the values of the quantity E of energy and of the flow F of gas are adapted according to the parameters mentioned above and coordinated with the mechanical movement of the support substrate and of the magnetron unit/s in order to keep each single layer of the overall thickness of the stratified deposition 12 of carbonaceous material uniform and homogeneous.

In particular, the plurality of sensors electrically connected to the data processing unit preferably includes at least one pressure sensor of the capacitive type and at least one gas flow sensor.

For each type of substrate 11 or 11a the data processing unit is configured to start the deposition phase with a predefined set of parameters (E, Hz, F), which is then adapted according to the data collected by the set of sensors positioned inside the vacuum chamber 110 during the course of the deposition step itself.

This ensures the necessary and optimal process repeatability, particularly necessary if several devices 10 or 10a are to be produced in series and have the same operating characteristics.

In use, the device 10 or 10a allows the rapid transfer of thermal energy in the presence of a thermal differential between the substrate 11 or 11a and the second face of the layer of upper carbonaceous material.

In particular, the structure of the layer or layers of carbonaceous material is such as to rapidly transfer thermal energy from a source of thermal energy A to an arrival point B at a speed higher than the convective and conductive capacity of the adjacent media, allowing to convert the thermal energy, captured and transferred, into electric energy with zero harmful emissions, for the environment and for living beings, by means of a conversion device 3 positioned at the arrival point B, effectively realizing a sort of thermal superconductor.

In this way, the thermal dispersion, for example from radiation towards the environment surrounding the device itself, is reduced to a minimum.

From some experiments carried out on a 12×27 mm sample whose part exposed (capturing) to thermal energy (hot and cold) due to the transport of thermal energy is equal to 8×14 mm, in which the layer of carbonaceous material is stratified with an overall thickness of 200 nm, with a range of differentials, 0.5° C., 1° C., 2° C., 3° C., 4° C., 5° C., 10° C., 20° C., by 30° C., by 40° C., by 50° C. and then −0.5° C., −1° C., −2° C., −3° C., −4° C., −5° C., −10° C., −20° C., −30° C., −40° C., −50° C., between the side of the substrate 11 and the exposed side of the carbonaceous material layer by kinetic energy analysis at the molecular÷atomic level elaborated by high vacuum SEM microscope it was detected an average thermal conductivity of 1570 W/(m K) with a maximum peak of 1750 W/(m K).

The device 10 or 10a can be integrated with a thermoelectric converter 20, capable of converting thermal energy into electrical energy.

Conveniently, the thermoelectric converter 20 can be applied at one side of the device 10 or 10a on a portion of the surface of the laminate 12, thus realizing a system for converting thermal energy into electrical energy.

The thermoelectric converter 20, which in detail has its first surface 20f resting directly on the stratification 12 applied on the support substrate 11 or 11a, is preferably made by means of one or a plurality of cells similar to Peltier or by a plurality of similarly thermocouples according to the Seebeck effect, through which the overall efficiency achieved by the system in thermal-electric conversion can reach 40% (peaks of 55% have also been detected in the laboratory).

Taking a device according to the present invention into consideration in the laboratory, it has been observed that with suitable thermoelectric converters, with a temperature differential equal to 50° C., having a heating or cooling of the stratification 12 of the device having an exposed surface equal to 1 m², electrical powers of 4000 W are obtained, which drop to 2700 W if the temperature differential is 40° C., to 1150 W if the temperature differential is 30° C., to 850 W if the temperature differential is 20° C., 550 W if the temperature differential is 10° C. or 300 W if the temperature differential is 5° C.

If the device object of the present invention is not subjected to a differential (therefore not able to produce electric energy), it can be triggered with the following procedure: by feeding the thermoelectric converter with an electric current, the converter itself will be subject to a temperature variation capable of causing the transfer of thermal energy between the layers of carbonaceous material present on the substrate.

This injection of energy (the quantity of electric energy to trigger the operation is quantifiable in 5÷6 W for about 120 seconds) will be used as a starting condition of unbalance to start the rapid transfer of thermal energy captured by the layer of carbonaceous material towards the thermoelectric converter 20.

A particularly efficient solution for configuring the Peltier-like cells is achieved by superimposing a pair of thermoelectric converters 20, i.e. in which each thermoelectric converter 20 has a first face or upper surface (technically definable as a “hot” face) and a second lower face or surface (technically definable as a “cold” face), and in which the second lower face of the first thermoelectric converter of said pair rests or in any case faces the first upper face of the second thermoelectric converter of said pair. In fact, a small heat sink or heat dissipator is often present on the second face, which if present does not allow the direct support of two contiguous surfaces of two distinct Peltier cells.

Advantageously, the described system allows a part of the dissipated thermal energy coming from the first thermoelectric converter to be recovered on the second thermoelectric converter.

As illustrated in FIG. 6, the device for the rapid transfer of thermal energy can be integrated in an energy recovery system for the production of electrical energy from renewable sources, in which a device for the rapid transfer of thermal energy according to the present invention is used coupled to a first generator of the thermoelectric type feeding an electronic group integrating a possible second generator of the kinetic type, a possible third generator of the photovoltaic type which can be assisted by a possible fourth device for the rapid transfer of thermal energy according to the present invention coupled to a second thermoelectric generator with the primary purpose of removing heat to maintain the best efficiency of the photovoltaic cells.

In detail, in this FIG. 6, the reference number 300 indicates the entire complex device 100 (for the capture and rapid transfer of the captured thermal energy) coupled to a first complex generator device 304 (thermoelectric for producing electric energy) . The system can be integrated with a possible second kinetic generator 310 connected to the group 315 (rectifier/rectifier) via line 311 and to a possible third photovoltaic generator 330 which can be assisted with a fourth system 330a (complex device 100, for capturing and the quick transfer of the captured thermal energy according to the present invention) coupled to a second complex generator device 331a (thermoelectric to produce electric energy) to maintain the best efficiency of the photovoltaic device 330.

The voltage converter unit 340 of the Buck-Boost type is connected at the input, via lines 302, 316, 331 and 332a, to the first generator 300, to the possible second generator 310, to the possible third generator 330 and to the possible fourth generator 330a and adjusts the output voltage for the correct power supply of the following groups:
370, Any Group of Accumulators for Energy Reserve;
380, electronic unit, with WI-FI card, for communication with a remote computer or smartphone;
390, any inverter group for the supply of single-phase electric current conforming to the normal civil network, for example: 230V, 50 Hz with neutral and earthing;
400, possible inverter group for the supply of three-phase electric current conforming to the normal civil/industrial network, for example 3×380V, 50 Hz with neutral N and grounding.

With reference to FIG. 6, the voltage converter 340 is connected at the output via the bipolar line (+ and −) 342 to the group 350 (accumulator charger) which, via the bipolar line (+ and −) 351, charges the accumulator group 370. Said output group 370 supplies in case of emergency the group 380 and the group 390 or the 400 through the (+) line 352 which connects to the (+) line 346 (outgoing from the group 340) having the same value of positive voltage.

For simplicity of representation, in FIG. 6, the electric lines 302, 316, 331, 332a, and 342 are represented by a single segment but are actually bipolar, they comprise a first positive electric conductor electrically isolated from a second negative electric conductor.

The 311 line is actually a bipolar or three-pole alternating current line (depending on the type of kinetic generator) where each individual conductor is electrically isolated from a second or third conductor.

Line 351 comprises a first positive electrical conductor electrically isolated from a second negative electrical conductor.

The positive (+) lines 346 outgoing from the respective capacitor banks 344 and 345 are joined by nodes to the line 352, being electrically isolated conductors having however the same type of electric current and the same voltage value.

The negative (−) or zero line 341a has at least two nodes and is actually the electrical zero of the system.

With reference to FIG. 6, coupled to the thermal energy transfer device there is a thermoelectric generator 301, which includes an electric line 302 at its output, being the first power supply of the voltage converter 340.

With reference to FIG. 6, a possible second kinetic generator 310 connected to the rectifier group 315, which includes the electric line 316 at its output being the possible second power supply of the voltage converter 340.

With reference to FIG. 6, a possible third photovoltaic generator 330, which includes the electric line 331 at its output being the possible third power supply of the voltage converter 340.

With reference to FIG. 6, coupled to the thermal energy transfer device 330a, having the primary purpose of maintaining the best efficiency of the photovoltaic generator 330 even in moments of strong solar radiation, there is a possible fourth thermoelectric generator 331a, which comprises in output an electric line 332a being the possible fourth power supply of the voltage converter 340.

Each input line to the voltage converter unit 340 supplies its own specific Buck-Boost device, therefore having possible different input voltage values which said voltage values become identical after the conversion performed by the single “Buck-Boost” devices and therefore output on a single (+) electric positive terminal to which the monopolar line 341 is connected and a single negative (−) or electric zero terminal to which the monopolar line 341a is connected.

Advantageously, the unit 340 has a second output with a (+) terminal and a (−) terminal dedicated to supplying, via the bipolar connection 342, a possible device 350 for charging one or more accumulators via the bipolar connection 351 (batteries) 370 for an advantageous energy reserve.

Advantageously, the accumulator charger group 350 is configured to disconnect the power supply for electric recharging to the accumulators (batteries) 370 when it detects that they are fully charged, so as to reduce their wear and improve their service life.

Using the 340 Voltage Converter with individual Buck-Boost devices is cost-effective as it allows the continuous voltage value to be increased or decreased from a first value coming from the thermoelectric generator 301 and/or from the kinetic generator 310 rectified by 315 and/or from the photovoltaic generator 330 and/or from the thermoelectric generator 331a each connected to a specific Buck-Boost device adapting the individual values of voltage to the value necessary to power, for example the group 390 or the group 400.

Advantageously said group 340, by adapting the voltage of the direct current produced by increasing it to the value necessary to power, for example, a delivery group 390 or a delivery group 400, allows to use even the small quantities of energy which would otherwise be lost because the voltage value is lower than the required threshold.

Advantageously said group 340, by adapting the voltage of the direct current produced by reducing it to the value necessary to power, for example, a delivery group 390 or a delivery group 400, also allows to use the energy that would otherwise be lost because the value voltage is higher than the required threshold.

Said output voltage converter 340 has, as mentioned, an electric positive (+) terminal which via a single-pole connection 341 supplies a two-position switch 343 or equivalent electronic switches of the static type which via the single-pole connections 343a and 343b supplies alternatively a first bank of capacitors 344 and a second bank of capacitors 345. Said voltage converter 340, at its output, has, as mentioned, a terminal (−) or electrical zero reference to which they are connected via connection 341a, with various nodes, groups 380 and 390 or 400.

Advantageously, said capacitor banks 344 and 345 ensure the positive (+) electric power supply, via the monopolar connections 346 possibly assisted by the monopolar connection 352 (+), of the data processing and communication unit (WI-FI) 380, of the eventual single-phase inverter 390 or any three-phase inverter 400.

Advantageously, any group 390 fed with a direct current at the input via the positive line 346 and the zero line 341a will supply a preferably sinusoidal alternating current compatible with the normal civil electrical network, for example single-phase 230V-50 Hz+neutral N and grounding.

Advantageously, any group 400 supplied at the input with a direct current via the positive line 346 and the zero line 341a will supply a preferably sinusoidal alternating current compatible with the normal industrial/civil electrical network, for example three-phase 3×380V-50 Hz+neutral N and mass to the ground.

Optionally both inverters 390 and 400 may be present and powered by lines 346 and 341a. Optionally, the presence of the accumulator group 370 is also possible and in this case an electrical energy transformation system is created in which whenever the absorption required by said system is greater than the electrical energy that can be supplied by the thermoelectric generator assembly 301 and if present, of the kinetic generator 310 connected via 311 to the rectifier 315, of the photovoltaic generator 330 assisted by the thermoelectric generator 331a, the accumulators 370 automatically intervene in the power supply providing the necessary energy.

Advantageously, the data processing and WI-FI communication unit 380 is supplied with a direct current input through the positive line 346 and the zero line 341a; by means of a microprocessor, it processes the input and output data coming from the 340, 350, 344, 345 and 390 group or 400 group and then transmits, via WI-FI on a computer or smartphone, to the remote control of the system of the present invention, the characteristic data relating to the operation of the individual groups, indicated in FIG. 6, by signaling any anomalies and indications relating to the maintenance methods.

Substantially said unit 380 allows to have an overall control of the operating status of the system, and for example of the quantity of energy produced by the generator/s and by the inverter for the electric network 390 and/or 400, or in case of malfunctions.

Thanks to the system described above (with reference to FIG. 6) various electrical applications both for civil use and for industrial use can be powered through the combination of different electricity generators from renewable sources such as:
Thermal energy, hot and cold, via thermoelectric generator 301;
Kinetic energy, flows of air or other fluids, via Kinetic generator 310 (+311 and 315);
Solar energy, light, through photovoltaic generator 330;
Thermal energy, heat to be dissipated to avoid overheating of the photovoltaic 330, by rapid transfer of thermal energy 330a and related thermoelectric generator 331a according to the present invention.

Said system described above, with reference to FIG. 6, combined with the possibility of integrating the accumulator group 370 creates a very effective integrated system both in the civil and in the industrial fields, the efficiency of which can be very high compared to electrical power supply systems from traditional renewables sources.

The kinetic generator and the photovoltaic generator can also be absent, but already only the presence of a system for the rapid transfer of thermal, hot or cold energy, coupled to a thermoelectric generator according to the present invention can ensure electricity for civil or industrial applications.

Furthermore, the presence of batteries or accumulators makes it possible to supply electricity even in the case of total absence of solar, thermal and kinetic energy components.

The system described above can therefore be installed in all those environments where there is no electrical distribution network and, at the same time, or where the supply of electrical power from the network is discontinuous with considerable advantages for maintaining the functioning of various equipment and, in any case, represents a significant energy saving.

Advantageously, in the system according to the present invention the device for transferring thermal energy also works in cold weather, provided there is a sufficient thermal differential. Therefore it is, for example, able to provide its contribution both during the winter months and during the summer months.

Finally, it is clear that modifications, additions and variations, obvious for a person skilled in the art, can be applied to the device for the rapid transfer of thermal energy coupled to a thermoelectric device described above, as well as to the manufacturing method and to the electronic system described above. without thereby departing from the scope of protection provided by the annexed claims.

1. Device 1 (10 or 10a) for capturing thermal energy from a thermal energy source (A) and rapidly transferring said thermal energy to an arrival point (B) at a speed higher than the convective and conductive capacity of the adjacent means.

2. Device 1 (10 or 10a) according to claim 1, wherein said thermal energy of the thermal source (A) is characterized by a temperature higher than 0° C. (zero degrees Celsius).

3. Device 1 (10 or 10a) according to claim 1, wherein said thermal energy of the thermal source (A) is characterized by a temperature lower than 0° C. (zero degrees Celsius).

4. Device 1 (10 or 10a) according to claim 1, wherein at least one surface is planar and is coated with a plurality of layers whose atoms form ordered geometric structures.

5. Device 1 (10 or 10a) according to claim 1, wherein at least one surface is not planar and is coated with a plurality of layers whose atoms form ordered geometric structures.

6. Device 1 (10 or 10a) according to claim 1, wherein the surface is flexible and is coated with a plurality of layers whose atoms form ordered geometric structures.

7. Device 1 (10 or 10a) according to claim 1, wherein the planar surface is a substrate, to be coated with a plurality of layers whose atoms form ordered geometric structures, consisting of solid material and rigid or semi-rigid, metallic or non-metallic, lacking transparency to visual light and possibly translucent or non-translucent.

8. Device 1 (10 or 10a) according to claim 1, wherein the planar surface is a substrate, to be coated with a plurality of layers whose atoms form ordered geometric structures, made up of solid material and rigid or semi-rigid, metallic or non-metallic, transparent to visual light and/or possibly translucent.

9. Device 1 (10 or 10a) according to claim 1, in which the non-planar surface is a substrate, to be coated with a plurality of layers whose atoms form ordered geometric structures, consisting of solid and rigid or semi-rigid material, metallic or non-metallic, lacking transparency to visual light and/or possibly translucent.

10. Device 1 (10 or 10a) according to claim 1, in which the non-planar surface is a substrate, to be coated with a plurality of layers whose atoms form ordered geometric structures, consisting of solid and rigid or semi-rigid material, non-metallic, transparent to visual light and/or possibly translucent.

11. Device 1 (10 or 10a) according to claim 1, wherein the surface is a flexible substrate, to be coated with a plurality of layers whose atoms form ordered geometric structures, consisting of woven material with natural or synthetic fibers or non-woven, metallic or non-metallic, transparent or non-transparent to visual light and/or possibly translucent.

12. Method for producing a device (10 or 10a), according to claims claim 1, for the rapid transfer of thermal energy: said method comprising at least one deposition step of at least one layer (12, 12a-12b-12c-12d, etc.) of carbonaceous material with ordered geometric structure on a support substrate (11 or 11a) in an environment (110) of a deposition machine (100); said environment being vacuum packed and isolated from the external environment under controlled temperature and pressure conditions; said deposition taking place along an orthogonal or locally radial direction to a plane or shape substantially identified by said support substrate (11 or 11a).

13. Method according to claim 12, wherein said deposition step comprises an acquisition step of at least one set of pressure and temperature values inside said isolated environment (110).

14. Method according to claim 12, wherein said deposition step comprises the generation of an electromagnetic field investing at least partially said substrate (11 or 11a) and an automatic control step of said intensity of said electromagnetic field by means of a data processing unit of said deposition machine (100).

15. A method according to claim 14 when dependent on claim 13, wherein said electromagnetic field strength is adequate according to at least part of said set of values.

16. Method according to claim 14 wherein said electromagnetic field is generated by a magnetron generator (120) and wherein said deposition step comprises a step of a relative movement between said magnetron generator (120) and said support substrate (11 or 11a).

17. Method according to claim 1. comprising a step of supplying said substrate (11 or 11a) with an electric voltage capable of allowing the variation of a percentage of sp³-type bonds with respect to a percentage of sp²-type bonds all inside said at least one layer (12, 12a-12b-12c-12d etc.) of carbonaceous material 4.

18. Method according to claims 16 comprising a plurality of deposition steps of layers (12, 12a-12b-12c-12d etc.) of carbonaceous material with an ordered geometric structure wherein in a first deposition step a first layer (12a) of carbonaceous material is superimposed on said substrate (11 or 11a) and in which in the subsequent steps further layers (12b, 12c, 12d, etc.) of carbonaceous material are superimposed on said first layer of carbonaceous material (12a) and comprising at least three successive deposition steps in which said substrate (11 or 11a) is subjected to a first electric voltage in correspondence with a first deposition step of said plurality of deposition steps and a second electric voltage, different from said first electric voltage, at a second deposition step of said plurality of deposition steps.

19. Device according to claim 1, for the rapid transfer of thermal energy, said device being characterized in that it comprises a support substrate (11 or 11a) and a plurality of layers (12, 12a-12b-12c-12d, etc. ) of carbonaceous material with an ordered geometric structure acting as a thermal conducting medium; said layers of carbonaceous material being superimposed on said support substrate (11 or 11a); said device further comprising thermoelectric conversion means (20), having at least a first surface and a second surface; said first and second surfaces being positioned at different distances from said substrate and being subjected in use to a thermal differential with respect to said first surface; said thermoelectric conversion means being capable of causing the production of electric energy starting from said temperature differential.

20. Device according to claim 12, wherein each of said layers of carbonaceous material contributes to characterizing the assembly of said layers of carbonaceous material as a thermoconductor or heat conducting allowing to transfer thermal energy at a speed higher than the convective and conductive capacity of the adjacent means.

21. Device according to claim 1, wherein each of said layers of carbonaceous material contributes to characterizing the assembly of said layers of carbonaceous material as a heat conductor allowing the rapid transfer of thermal energy at a speed higher than the convective and conductive capacity of the means adjacent also conferring the characteristic of flexibility.

22. Device according to claim 1, wherein each of said layers (12, 12a-12b-12c-12d, etc.) of material the carbonaceous has a predetermined percentage amount of bonds of the sp³ type (major), and a predetermined percentage amount of bonds of the sp² type (minor).

23. Device according to claim 1, wherein said thermoelectric conversion means comprise at least one Peltier-like cell or at least one similar thermocouple according to the Seebeck effect.

24. Device according to claim 23, wherein said thermoelectric conversion means further comprises a second Peltier-like cell, and wherein each of said first, second Peltier-like cells comprises said first and second surfaces; said second surface of said first Peltier-like cell being positioned in substantial proximity to said first surface of said second Peltier-like cell providing a means of recovering residual energy (heat) generated by the operation of said first Peltier-like cell.

25. Integrated power supply system for electrical loads from renewable energy sources, said system comprising at least one device for transferring thermal energy according to claim 2, physically coupled to a thermoelectric converter (301) and other heat generating means electricity from renewable sources (310-315, 330, 331a); said thermoelectric converter having respective outputs electrically connected and supplying at least one electric energy transformation stage (390 or 400) for supplying civil or industrial electrical devices or loads.

26. System according to claim 25, further comprising an electric energy storage stage (370), electrically connected to said electric energy transformation stage (390 or 400) and configured to supply with a continuous type electric energy stored by them and coming from said thermoelectric converter (301) and/or from other generators of electric energy from renewable sources (310-315, 330, 331a) to said power supply of said electric energy transformation stage (390 or 400) in case of power supply electricity absent from said thermoelectric converter (301) and/or from the other generators of electricity from renewable sources (310-315, 330, 331a).

27. System according to claim 25, further comprising an electric energy accumulator stage (370) electrically connected with said thermoelectric converter, with said generators of electric energy from renewable sources (310-315, 330, 331a) and with said transformation stage of electric energy by means of a charge regulator stage (350) capable of feeding said electric energy accumulator stage (370) at least when partially discharged, said charge regulator stage replacing the power supply of said electric energy transformation stage (390 or 400) when an electric energy absorption required by said electric energy transformation stage (390 or 400) is higher than the electric energy supplied to it by said thermoelectric converter (301) and/or by said generators of electricity from renewable sources (310-315, 330, 331a).

28. System according to claim 25, further comprising at least one kinetic electric energy generator (310-315), capable of supplying jointly with said thermoelectric converter (301) and/or the other said electric energy generators from renewable sources (330, 331a) the said electric energy transformation stage (390 or 400).

29. System according to claim 25, further comprising a Buck-Boost type voltage converter (340), comprising separate inputs and individually powered by said thermoelectric converter (301) and/or by the others said generators of electricity from renewable sources (310-315, 330, 331a), said output voltage converter feeds said charge regulator stage (350) at the input and alternatively feeds the capacitor bank (344) and the capacitor bank (345) via a two-position switch or, preferably, via two electronic switches static type, said capacitor banks (340 and 345) alternately feed said electric energy transformation stages (390 and/or 400) and said data processing and wireless communication via WI-FI stage (380).

30. System according to claim 25, wherein the eventual said photovoltaic generator (330) is assisted by a rapid thermal energy transfer system (330a) coupled to said thermoelectric generator (331a).
